(19) United States
(12) Patent Application Publication
(10) Pub. No.: US 2023/0235446 A1
(43) Pub. Date: Jul. 27, 2023

(54) METHOD FOR FURTHER IMPROVING LASER PULSED DEPOSITION EFFICIENCY

(71) Applicant: NORSELD PTY LT, Adelaide (AU)

(72) Inventors: Alexandre FRANCOIS, Adelaide (AU); Nathan HOLMES, Adelaide (AU)

(21) Appl. No.: 18/013,006

(22) PCT Filed: Jun. 24, 2021
(86) PCT No.: PCT/AU2021/050661

§ 371 Date: Dec. 27, 2022

(30) Foreign Application Priority Data
Jun. 25, 2020 (AU) 2020902132
Oct. 9, 2020 (AU) 2020903664

(51) Int. Cl. C23C 14/28; C23C 14/06; C23C 14/54

(52) U.S. Cl. CPC C23C 14/28; C23C 14/54; C23C 14/0605

(57) ABSTRACT

A thin film deposition apparatus comprising: a laser pulse generator to generate a laser pulse; optical elements to optionally P-polarize and optionally rotate the laser pulse polarization with a polarization angle φ based on the cavity chamber and deposition material; focusing optics to focus the laser pulse; a source of deposition material having refractive index n₂; said deposition material mounted within an evacuated chamber having a refractive index n₁; a rotation and / or translation device to alter and / or direct said laser pulse onto said source of deposition material at an incidence angle θ to produce a plasma to be deposited on a substrate; wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁).

### BACKGROUND OF THE INVENTION

Pulsed Laser Deposition (PLD), a physical deposition method, is an attractive alternative to Chemical Vapor Deposition (CVD) and its plurality of variations as PLD allows for the deposition of thin films with controlled stoichiometry at room temperature. This enables the coating of complex materials onto a wide variety of substrate materials ranging from glass to metal and polymers. PLD also permits the deposition of thin films onto fragile substrates, such as polymers, which could not sustain the high temperature involved in other deposition methods.

PLD, in its simplest form, involves directing a high intensity pulsed laser beam onto a source of deposition material, located in a high vacuum chamber, which upon impact produces a wide range of physical effects including melting and ablation of the target material. The subsequently created plasma of atoms and ionized species, ejected from the source of deposition material, follows an almost linear normal trajectory in the high vacuum chamber from the source of deposition material to the substrate where it condenses to form the deposited film.

A wide variety of pulsed laser sources have been investigated for PLD, with wavelengths ranging from the deep UV to the infra-red. Both solid state and gas plasma lasers can produce pulsed laser beam in the UV (i.e. below 400 nm), which have tended to be more suitable for PLD. Solid state lasers rely on a crystal host (i.e. YAG, YLiF₄, YVO₄ etc...) or an optical fibre, doped with a rare earth element (i.e. Nd, Y, Er etc...) to generate light, typically in the infra-red region of the optical spectrum.

Sophisticated non-linear effects such as frequency doubling, frequency tripling or sum frequency generation are typically required to transform the longer emitted wavelengths into shorter ones. Each of the non-linear steps required significantly affect the laser efficiency, meaning that generating deep UV wavelengths from solid state lasers is inefficient. Gas plasma lasers produce light by discharging an electric current through a gas. The emitted wavelength is dictated by the gas used. However, the pulsed laser beam produced by some gas plasma lasers is intrinsically non-polarized, unlike solid state lasers, thereby requiring additional optical components to induce a specific polarization of the emitted light as shown by Rothe et al. (Proc. SPIE Vol. 2513 (1995)).

Beside the use of different wavelengths, multiple variations of PLD have been developed to improve the performance of the deposition process, whether in terms of deposition rate, homogeneity of the deposited thin film or better control of the deposited film stoichiometry. Such methods include using multiple pulsed laser beams, as shown by Darwish et al. (US 2014/0227461A1) to ablate different target materials concurrently, thereby allowing the deposition of complex composite materials. Selvamanickam et al. (US 7,501,145 B2) have used multiple pulsed laser beams focussed on different targets of the same material to increase the deposition throughput. Similarly, efforts have been reported in the literature (Tselev et al. Rev. Sci. Ins. 72, 6, 2665-2672, Witanachchi et al. US 5,660,746) to improve the efficiency of the pulsed laser deposition process, notably by increasing the kinetic energy of the ablated ion species and reducing nanoparticle formation, using two different pulsed laser beams, emitting at different wavelengths, focussed on either a single target or two targets of the same material to be ablated. Other approaches to induce better control of the PLD process include filtering the flux of ions from the plasma plume with a magnetic field (US 6,024,851), thereby selecting only specific ion species for their subsequent deposition onto a substrate, or engineering the shape of the target material and how the pulsed laser beam interact with the target in specific ways in order to increase the rate at which material is removed from the target (WO 2016/102757A1).

The reference to any prior art in this specification is not, and should not be taken as, an acknowledgement or any form of suggestion that the prior art forms part of the common general knowledge.

### SUMMARY OF THE INVENTION

It is an object of the present invention to provide a method for improving the efficiency of PLD for thin film deposition.

In one aspect of the invention, there is provided a thin film deposition apparatus comprising: a laser pulse generator to generate a laser pulse; optical elements to optionally P-polarize and optionally rotate the laser pulse polarization with a polarization angle φ based on the cavity chamber and deposition material; focusing optics to focus the laser pulse; a source of deposition material having refractive index n₂; said deposition material mounted within an evacuated chamber having a refractive index n₁; a rotation and / or translation device to alter and / or direct said laser pulse onto said source of deposition material at an incidence angle θ to produce a plasma to be deposited on a substrate; wherein the polarization angle φ and incidence angle θ are defined by the area under the graphical representation of the ellipse of quation

$$\frac{{\left(θ - {θ}_{0}\right)}^{2}}{{a}^{2}} +$$

$$\frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁).

In another aspect of the invention, there is provided a method of thin film deposition comprising: generating a laser pulse; optionally P-polarizing and optionally rotating the laser pulse polarization with a polarization angle φ based on the cavity chamber and deposition material; focusing the laser pulse; directing the laser pulse onto a source of deposition material at an incidence angle θ to produce a plasma to be deposited on a substrate; wherein the polarization angle φ and incidence angle θ are defined by the area under the graphical representation of the ellipse of equation

$$\frac{{\left(θ - {θ}_{0}\right)}^{2}}{{a}^{2}} +$$

$$\frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁).

The laser pulse generator may be of any suitable type. In some preferred embodiments, it comprises an excimer laser pulse generator comprising KrF as gain medium. The wavelength may be of any suitable length and in some embodiments it is less than 1064 nm, or less than 600 nm. In some embodiments the laser pulse wavelength is about 532 nm and in some it is in the range 213 to 355 nm. In some embodiments it is in the range 126 to 348 nm. In one particularly preferred embodiment it is 248 nm or about 248 nm. In another particularly preferred embodiment it is 198 nm or about 198 nm.

The pulse duration can be a range of values suitable for the application at hand and preferably in the range 1 femtosecond to 50 nanoseconds and more preferably in the range 5-30 nanoseconds.

The optical elements used to optionally P-polarize and optionally rotate the laser pulse polarization optionally may comprise one or more of a film polarizer, a crystal polarizing cube, a wire grid polarizer, a Brewster window, a λ/4 plate, a λ/2 plate, and a faraday rotator.

The deposition material may comprise one or more of: a carbon source, a graphite, highly oriented pyrolytic graphite, a complex metal oxide, Lithium Niobate (LiNbO3), a high temperature superconductor, LiTi₂O₄, Li₄Ti₅O₁₂, YBa₂Cu₃O₇, a ferroelectric material, BaₓSr₁₋ₓTiO₃, a piezoelectric, Ta₂O₅, a fast ion conductor, Y₂(Sn_{y}Ti_{1-y})₂O₇, a liquid petroleum gas sensor, and Pd-doped SnO₂.

The pressure within the evacuated chamber is ideally as low as commercially feasible for the application at hand. In some embodiments, it is in the range 10⁻⁴ to 10⁻¹² Torr and in others it is in the range 10⁻⁴ to 10⁻⁸ Torr. In one preferred embodiment it is in the range 10⁻⁶ to 10⁻⁸ Torr.

In some preferred embodiments, the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=arctan (n₂/n₁), φ₀=0, a=1 and b=1.

One preferred embodiment comprises a thin film deposition apparatus comprising: an excimer laser pulse generator with KrF as gain medium to generate a laser pulse with wavelength of 248 nm and pulse duration of 5 to 30 nanoseconds; a set of optical elements, comprising a sequence of λ/4 plate then λ/2 plate then λ/4 plate to linearly P-polarize the laser pulse and rotate the laser pulse polarization with a polarization angle φ based on the cavity chamber and deposition material; focusing optics to focus the laser pulse; a source of deposition material comprising highly oriented pyrolytic graphite and having refractive index n₂; said deposition material optionally mounted on a rotation and / or translation device within an evacuated chamber having a refractive index n₁ and pressure within the evacuated chamber in the range 10⁻⁶ to 10⁻⁸ Torr; a rotation and / or translation device comprising a dielectric mirror, for readily altering and directing said laser pulse onto said source of deposition material at an incidence angle θ to produce a plasma; a substrate; means for positioning said substrate to be in the path of said plasma so that said plasma is directed towards said substrate; wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=arctan (n₂/n₁), φ₀=0, a=1 and b=1.

In another preferred embodiment, there is provided a method of thin film deposition comprising: using an excimer laser pulse generator with KrF as gain medium to generate a laser pulse with wavelength 248 nm and pulse duration of 5 to 30 nanoseconds; passing the laser pulse through a sequence of λ/4 plate then λ/2 plate then λ/4 plate to linearly P-polarise and rotate the laser pulse polarization to a polarization angle φ based on the cavity chamber and a chosen source of deposition material; focusing the laser pulse; directing via a dielectric mirror said laser pulse onto said source of deposition material at an incidence angle θ to produce a plasma; positioning a substrate in the path of said plasma; wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=arctan (n₂/n₁), φ₀=0, a=1 and b=1.

While more exotic and often convoluted methods have been devised for increasing the PLD throughput, the purpose of the present invention is to improve the efficiency of the ablation process in PLD thereby reducing the energy requirement for a given target material to be ablated without necessitating complex illumination of the target by the pulsed laser beam, or multiple pulsed laser beams. The invention in some aspects reduces the reflectivity of the target material by selecting a combination of incidence angle and polarization state of the pulsed laser beam onto the target material, thereby increasing the resulting light matter interaction.

Several parameters are important for PLD such as the pressure in the vacuum chamber, the laser wavelength, pulse duration and fluence (i.e. laser pulse energy per surface area). These parameters tend to be interdependent and strongly affected by the nature of the source of deposition material.

The present invention generally relates to improving the energy transfer of the incoming pulsed laser beam to the source of deposition material by reducing the reflected component of the incoming beam, consequently producing higher absorption up to 100% of the incoming pulsed laser beam. The invention takes advantage of both the polarized nature of the incoming laser beam and the Fresnel coefficient of the source of deposition material to determine both the optimum incidence angle and polarization of the incoming pulsed laser beam to minimize and in some case negate the incoming pulsed laser beam reflection.

The vast majority of current PLD systems described in the literature exhibit a 45 deg incidence angle of the incoming pulsed laser beam onto the source of deposition material. Furthermore, there is scant information regarding the polarization state of the pulsed laser used for such systems which can be either linearly or elliptically polarized. Considering these parameters and the nature of the source of deposition material, the reflectance of the pulsed laser beam can easily reach 40%, which is representative of the amount of energy eventually being lost and therefore not contributing to the ablation of the source of deposition material.

According to another aspect of the invention there is provided a thin film deposition apparatus, comprising: a laser pulse generator to generate at least one laser pulse; a source of deposition material having refractive index n₂; said deposition source within an evacuated chamber, the chamber cavity having a refractive index n₁; means for directing said at least one laser pulse onto said source of deposition material at an incidence angle θ to produce a plasma; a substrate; means for positioning said substrate to be in the path of said plasma so that said plasma is directed toward said substrate; means for delivering said at least one laser pulse with a defined linear polarization with a polarization angle φ between the oscillating electric field of the laser pulse and the plane of incidence onto the source of deposition material; wherein incidence angle θ equals arctan(n₂/n₁) and polarization angle φ equals 0 (P-polarized laser pulse) in a preferred embodiment, or in some embodiments any combination of incidence angle θ and polarization angle φ defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁), wherein ablation efficiency is improved compared to the standard incidence angle of 45 deg with either an unpolarized laser pulse or linearly polarized laser pulse with a polarization angle φ ranging from 0.5× arctan (n₂/n₁) to π/2. In some embodiments, the apparatus comprises focusing optics to focus the laser pulse. Some embodiments comprise polarizing optics to generate a linearly polarized laser beam with a polarization angle φ ranging from 0 to 0.5× arctan (n₂/n₁), or preferably with a polarization angle φ=0 defined as a P-polarized laser beam and some comprise polarization rotation optics to rotate a linearly polarized pulsed laser beam, preferably resulting in a P-polarized laser beam.

According to another aspect of the invention there is provided a thin film deposition apparatus, comprising: a laser pulse generator to generate at least one laser pulse; a set of optical elements to polarize the laser pulse and/or rotate the laser pulse polarization with a polarization angle φ; a source of deposition material having refractive index n₂; said deposition source within an evacuated chamber, the chamber cavity having a refractive index n₁; means for directing said at least one laser pulse onto said source of deposition material at an incidence angle θ to produce a plasma; a substrate; means for positioning said substrate to be in the path of said plasma so that said plasma is directed towards said substrate.

In some embodiments, the optical elements are set to linearly polarize the pulse laser with a polarization angle φ wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁). The optical elements may be set to linearly polarize the pulse laser with a polarization angle φ wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=arctan (n₂/n₁), φ₀=0, a=1 and b=1.

In some embodiments, the apparatus of the invention comprises a rotation/translation device to direct the laser beam on to the source of deposition material at a required incidence angle.

In some preferred embodiments, the incidence angle θ=arctan (n₂/n₁) and polarization angle φ=0. In some embodiments, the apparatus of the invention comprises focusing optics to focus the laser pulse and in some it comprises a means to readily alter the incidence angle θ and the polarization angle φ based on the cavity chamber and deposition material. This refers to the necessary angular adjustment required when changing the target material. In practice, the polarization angle φ will rarely require adjustment provided that it is p-polarized or close to. According to the present invention, the incidence angle θ needs to be as close as possible to the Brewster angle which depends on the refractive index of the target material and the vacuum. If several target materials are located into the vacuum chamber, such as for example, graphite and chromium, which is often deposited first to promote the adhesion of the subsequently deposited thin film (DLC for instance), an adjustment of the incidence angle θ is required to operate in the optimum conditions while switching between the different target materials. Altering the incidence angle θ can be readily achieved by tilting the mirrors that direct the incident beam into the chamber.

The duration of the laser pulse may be of any suitable length and in some embodiments it is in the range of 1 femtosecond to 50 nanoseconds. Whilst shorter pulses, in the 1 -100 femtosecond range can be beneficial, they can also be quite impractical for industrial applications, because they have very low pulse energy, preventing the pulse laser beam to generate sufficient ablation and/or generate ionic species with sufficient kinetic energies. In some preferred embodiments, 5-30 nanosecond pulses are used.

The pressure within the evacuated chamber may be of any suitable amount. The lower the pressure within the chamber, the less species in the chamber to collide with the deposition material ions and so less dampening will occur and a more efficient process results. However, it is time consuming (4-6 hours for a 50×50×50 cm³ chamber) and requires expensive pumps to reduce the pressure within the chamber. It has been found that a reasonable compromise in pressure within the evacuated chamber is in the range 10⁻⁴ to 10⁻¹² Torr, in some, it is in the range 10⁻⁴ to 10⁻⁸ Torr and preferably in the range 10⁻⁶ to 10⁻⁸ Torr.

The wavelength of the laser pulse may be of any suitable size, in some embodiments it is 1064 nm or less and in some it is about 1064 nm. In some embodiments the wavelength of the laser pulse is 600 nm or less and in some it is about 532 nm. In some embodiments, the wavelength is in the ultraviolet part of the optical spectrum. In some embodiments, the wavelength is below 355 nm produced by the harmonics of a solid-state laser pulse generator and in some it is below 348 nm produced by an Excimer laser pulse generator. In some embodiments, the wavelength is about 248 nm. In some embodiments, the wavelength is within the visible or near infra-red or infra-red parts of the electromagnetic spectrum. In some embodiments, the wavelength is selected from 532 nm, 1064 nm and 10.6 µm. In some preferred embodiments of the apparatus of the invention there is provided a means to readily alter the incidence angle to suit both the refractive indices n₁ of the cavity chamber and n₂ of the source of deposition material. The duration of the laser pulse can be any suitable period of time, in some embodiments the duration of the laser pulse is in the range of 1 femtosecond to 50 nanoseconds. Whilst shorter pulses, in the 1 -100 femtosecond range can be beneficial, they can also be quite impractical for industrial applications, because they have very low pulse energy. In some preferred embodiments, 5-30 nanosecond pulses are used.

The pressure within the evacuated chamber should be sufficient to enable the process to work. In some preferred embodiments, the pressure within the evacuated chamber is in the range 10⁻⁴ to 10⁻¹² Torr or in the range 10⁻⁴ to 10⁻⁸ Torr or 10⁻⁶ to 10⁻⁸ Torr.

A variety of laser pulse wavelengths may be used with the apparatus of the invention, for example, in some embodiments the wavelength of the laser pulse is 1064 nm or less. In some embodiments the wavelength of the laser pulse is about 1064 nm. In some embodiments, the wavelength of the laser pulse is 600 nm or less and in some embodiments it is about 532 nm. In some embodiments, the wavelength is in the ultraviolet part of the spectrum and may for example be in the range 213 to 355 nm produced by higher harmonics from solid state lasers. In some applications, the wavelength is in the range 126 to 348 nm for example produced by Excimer lasers. And in some embodiments the wavelength is or is about 248 nm. In other embodiments, the wavelength is within the visible or near infra-red or infra-red parts of the electromagnetic spectrum. In some applications, the wavelength is selected from 532 nm, 1064 nm and 10.6 µm.

Some preferred embodiments of the invention comprise a rotation/translation device to direct the laser beam on to the source of deposition material at a required incidence angle.

In another aspect of the invention, there is provided a method of thin film deposition comprising: generating a laser pulse; linearly polarizing said laser pulse with a polarization angle φ, defined as the angle between the electric field of the laser pulse and the plane of incidence onto the source of deposition material; directing the laser pulse at an incidence angle θ to produce a plasma from a source of deposition material having a refractive index n₂, within an evacuated chamber having refractive index n₁; positioning said substrate to be in the path of said plasma so that said plasma is directed towards said substrate; wherein incidence angle θ = arctan (n₂/n₁) and polarization angle φ=0, or in some embodiments any combination of incidence angle θ and polarization angle φ defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁), wherein ablation efficiency is improved compared to the standard incidence angle of 45 deg with either an unpolarized laser pulse or linearly polarized laser pulse with a polarization angle φ ranging from 0.5× arctan (n₂/n₁) to π/2.

In another aspect of the invention, there is provided a method of thin film deposition comprising: generating a laser pulse; linearly polarizing said laser pulse with a polarization angle φ; directing the laser pulse at an incidence angle θ to produce a plasma from a source of deposition material within an evacuated chamber having refractive index n₁; positioning said substrate to be in the path of said plasma so that said plasma is directed towards said substrate.

In some embodiments, the method of the invention comprises the step of directing the laser pulse onto a source of deposition material with an incidence angle θ and linearly polarizing the pulse laser with a polarization angle φ wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=0.8× arctan (n₂/n₁), φ₀=0, a=0.4× arctan (n₂/n₁) and b=0.5× arctan (n₂/n₁).

In some embodiments, the method comprises directing the laser pulse onto a source of deposition material with an incidence angle θ and linearly polarizing the pulse laser with a polarization angle φ wherein the polarization angle φ and incidence angle θ are defined by the area under the graphical representation of the ellipse of equation

$$\frac{{\left(θ - {θ}_{0}\right)}^{2}}{{a}^{2}} + \frac{{\left(φ - {φ}_{0}\right)}^{2}}{{b}^{2}} = 1$$

where θ₀=arctan (n₂/n₁), φ₀=0, a=1 and b=1. In other embodiments, the method comprises directing the laser pulse onto a source of deposition material with an incidence angle θ=arctan (n₂/n₁) and linearly polarizing the pulse laser with a polarization angle φ=0.

The laser pulse may be focused and in some embodiments, there is a step of altering the incidence angle θ and the polarization angle φ based on the cavity chamber and deposition material.

The duration of the laser pulse may be of any suitable length and in some embodiments it is in the range of 1 femtosecond to 50 nanoseconds. Whilst shorter pulses, in the 1 -100 femtosecond range can be beneficial, they can also be quite impractical for industrial applications, because they have very low pulse energy. In some preferred embodiments, 5-30 nanosecond pulses are used.

Similarly, the pressure within the evacuated chamber may be of any suitable amount, and in some embodiments it is in the range 10⁻⁴ to 10⁻¹² Torr and in some, it is in the range 10⁻⁴ to 10⁻⁸ Torr.

The wavelength of the laser pulse may be of any suitable size, in some embodiments it is 1064 nm or less and in some it is about 1064 nm. In some embodiments the wavelength of the laser pulse is 600 nm or less and in some it is about 532 nm. In some embodiments, the wavelength is in the ultraviolet part of the optical spectrum. In some embodiments, the wavelength is below 355 nm produced by the harmonics of a solid-state laser pulse generator and in some it is below 348 nm produced by an Excimer laser pulse generator. In some embodiments, the wavelength is about 248 nm. In some embodiments, the wavelength is within the visible or near infra-red or infra-red parts of the electromagnetic spectrum. In some embodiments, the wavelength is selected from 532 nm, 1064 nm and 10.6 µm.

The method of the invention may comprise additional steps relating to polarization of the laser pulse as required, for example it may comprise one or more of the steps of focusing the laser pulse, linearly polarizing the laser pulse with a polarization angle φ ranging from 0 to 0.5× arctan (n₂/n₁) or preferably P-polarizing (φ=0) the laser pulse, rotating the linear polarization of the laser pulse, with a polarization angle φ a P-polarized laser beam. In some preferred embodiments, the method comprises altering the both the incidence angle and polarization angle to suit the cavity chamber and deposition material refractive indices n₁ and n₂ respectively.

The duration of the laser pulse may be maintained at a variety of periods. Some embodiments comprise maintaining the duration of the laser pulse in the range of 1 femtosecond to 50 nanoseconds. Whilst shorter pulses, in the 1 -100 femtosecond range can be beneficial, they can also be quite impractical for industrial applications, because they have very low pulse energy. In some preferred embodiments, 5-30 nanosecond pulses are used.

The pressure within the evacuated chamber may be maintained at different levels, for example in some embodiments it is maintained in the range 10⁻⁴ to 10⁻¹² Torr or in the range 10⁻⁴ to 10⁻⁸ Torr or 10⁻⁶ to 10⁻⁸ Torr.

A variety of laser pulse wavelengths may be used with the method of the invention, for example, in some embodiments the wavelength of the generated laser pulse is 1064 nm or less. In some embodiments the wavelength of the laser pulse generated is about 1064 nm. In some embodiments, the wavelength of the laser pulse generated is 600 nm or less and in some embodiments it is about 532 nm. In some embodiment, the wavelength is generated in the ultraviolet part of the spectrum and may for example be in the range 213 to 355 nm produced by higher harmonics from solid state lasers. In some applications, the wavelength of the generated laser pulse is in the range 126 to 348 nm produced by Excimer lasers. And in some embodiments the wavelength generated is or is about 248 nm. In other embodiments, the wavelength generated is within the visible or near infra-red or infra-red parts of the electromagnetic spectrum. In some applications, the wavelength generated is selected from 532 nm, 1064 nm and 10.6 µm.

Some preferred embodiments of the invention comprise the step of directing the laser beam on to the source of deposition material at a required incidence angle.

Throughout this specification (including any claims which follow), unless the context requires otherwise, the word ‘comprise’, and variations such as ‘comprises’ and ‘comprising’, will be understood to imply the inclusion of a stated integer or step or group of integers or steps but not the exclusion of any other integer or step or group of integers or steps.

### DESCRIPTION OF THE DRAWINGS

FIG. 1 shows an example Pulsed Laser Deposition system of this invention with a linearly polarized laser beam focussed onto a target material with an incidence angle θ_{B} corresponding to the Brewster angle.

FIG. 2 shows an electromagnetic wave propagating along the Z axis, with the electric field component (plain line) oscillating along the Y axis and the magnetic field component (dashed line) oscillating along the X axis.

FIG. 3 illustrates the definition of S and P polarizations for linearly polarized pulse laser beam

FIG. 4 shows the definition of the polarization angle φ between the electric field component of the pulsed laser beam and the plane of incidence, thereby defining S (φ=π/2), P (φ=0) and arbitrary linear polarizations (0<φ<π/2).

FIG. 5 shows the calculated reflectance of a graphite target as function of the laser beam incidence angle with respect to the normal of the target for (A) 266 nm, (B) 355 nm and (C) 532 nm incident wavelengths.

FIG. 6 shows the calculated surface temperature on a graphite deposition source as function of the fluence of a 532 nm pulsed laser.

FIG. 7 shows the calculated kinetic energy of different carbon species vaporized from a graphite deposition source by a 532 nm pulsed laser at 15 J/cm² for two incidence angles, 45 deg and Brewster angle.

FIG. 8 shows the calculated kinetic energy of neutral carbon atom ablated from a graphite deposition source as function of the incidence angle for 3 different polarization states of a 248 nm pulsed laser with a fluence of 60 J/cm².

FIG. 9 shows the calculated kinetic energy increase for carbon species between a P-polarized pulsed laser beam at Brewster angle incidence against a circularly polarized pulsed laser beam at 45 deg incidence for different wavelengths.

FIG. 10 shows the contour plot of the percentage increase of kinetic energy of ejected carbon atoms from a graphite source of deposition material as function of both the polarization angle φ of the pulsed laser beam and the incidence angle θ for a 60 J/cm² pulsed laser fluence at 248 nm.

FIG. 11 shows the isolines for fixed percentage increase of the kinetic energy of neutral atoms (0%, 5%, 10%, 15%, 20%, 25%, 30%, 35% and 40%), ablated from a graphite source of material deposition with a 248 nm pulsed laser at a 60 J/cm² fluence. The fitted ellipses for each fixed percentage increase of the kinetic energy are shown as dashed lines and the ideal fitted ellipse centred at θ₀=0.8×θ_{B} and φ₀=0, with a long and short axis equal to 0.5×θ_{B} and 0.4×θ_{B} respectively, is shown as a plain line.

FIG. 12 shows an apparatus for steering the incident pulsed laser beam onto the target at different incidence angles.

FIG. 13 shows the Brewster angle in degrees as function of the target refractive index assuming a refractive index in the vacuum chamber n₁=1. Several materials with different refractive indices at 248 nm wavelength are shown as examples.

FIGS. 14A-14D shows the isolines for fixed percentage increase of the kinetic energy of neutral atoms (from 0% to the maximum percentage increase with a 5% increment), ablated from a (A) a Silver, (B) gold, (C) TiO₂ and (D) Ta₂O₅ source of material deposition with a 248 nm pulsed laser at a 60 J/cm² fluence. The ideal fitted ellipse centred at θ₀=0.8×θ_{B} and φ₀=0, with a long and short axis equal to 0.5×θ_{B} and 0.4×θ_{B} respectively, is shown as a plain line for each of the figures.

### DETAILED DESCRIPTION OF THE INVENTION

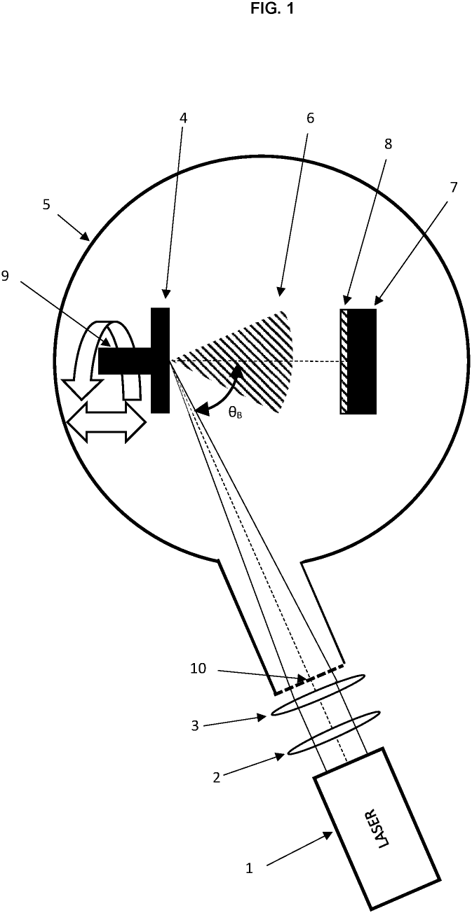

Referencing FIG. 1, a basic embodiment of the present invention is illustrated. Generally, the PLD system includes a pulsed laser source 1, polarization optics 2 and focussing optics 3, to produce a linearly P-polarized laser beam focussed into the target material 4 at an incidence angle θ_{B}, corresponding to the Brewster angle and defined as the arctan of the ratio of the refractive indices of the target and its surrounding environment. The polarization rotation optics 2, which can be a λ/2 plate, a Faraday rotator or any other polarization rotation device known to someone skilled in the art, is meant for a linearly polarized laser source. If the laser source is linearly polarized, then a λ/2 plate will allow to rotate the polarization axis along the preferred axis (p-polarized). If the laser source is circularly polarized, then a λ/4 plate will transform the circular polarization into a linear one and the addition λ/2 plate will allow to rotate the polarization axis along the preferred axis (p-polarized). If the laser source is randomly polarized (elliptical polarization for example for an excimer/gas plasma lasers), then a λ/4 plate + λ/2 plate + λ/4 plate will transform any polarization state into an arbitrary polarization output, preferentially a P-polarized beam. A polarizer (film, crystal, wire grid) behaves like a filter and only allows a specific polarization to go through. The selection of the polarization is performed by rotating the polarized and matching its fast axis with the desired polarization output. The main disadvantage with a polarizer is that all the light that is not transmitted through the polarizer is lost thereby negating the advantage provided by the invention. A Brewster window is similar to a polarizer although only P-polarized light can go through (i.e. no selection possible). A faraday rotator is very similar to a λ/2 plate, but can be remotely driven by a magnetic field to rotate the polarization. In particularly preferred embodiments comprising an excimer laser, a combination of λ/4 plate + λ/2 plate + λ/4 plate is preferred.

A circularly polarized or elliptically polarized pulsed laser source would require more complex polarization optics with a polarizer such as a film polarizer, crystal polarizing cube, wire grid polarizer, Brewster window or any other light polarizing device known to someone skilled in the art, to linearly polarize the pulsed laser beam, in addition to the aforementioned polarization rotation apparatus.

The ablation of the source of deposition material occurs in a high vacuum chamber 5, under a pressure ranging from 10⁻⁴ to 10⁻¹² Torr or in some preferred embodiments, 10⁻⁴ to 10⁻⁸ Torr or 10⁻⁶ to 10⁻⁸ Torr, allowing the creation of a plasma plume of ejected atom and ionized species 6 from the source of deposition material, each time a single pulse from the P-polarized pulsed laser source hits the source of deposition material. The plasma plume 6, propagating inside the vacuum chamber 5, reaches the substrate 7, where it condenses to form a thin film 8.

The source of deposition material can be mounted on a rotation/translation device 9, allowing for the incoming laser beam to hit a different spot on the source of deposition material surface and to maintain the source of deposition material surface at the focal point of the focussing optics 2.

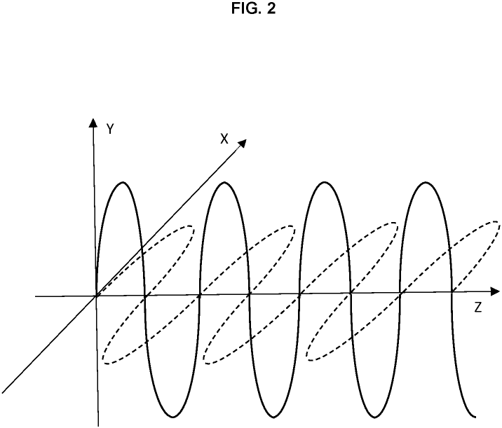

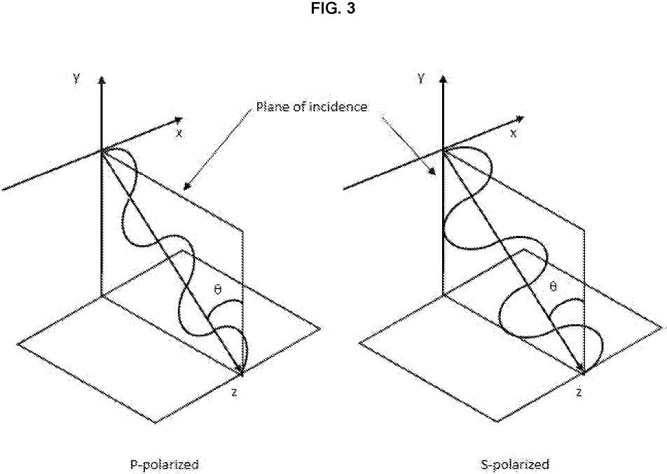

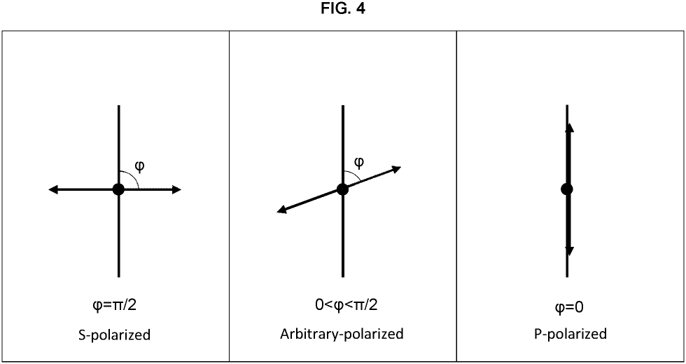

For clarity, we define the pulsed laser beam as an electromagnetic wave as shown in FIG. 2, propagating along the Z axis, with an oscillating electric field perpendicular to the propagation axis and an oscillating magnetic field perpendicular to both the propagation axis and the oscillating electric field. Someone skilled in the art will appreciate that while the electric field is represented in FIG. 2 as oscillating along the Y axis, it can be oscillating along the X axis or anywhere in the XY pane as long as it remains perpendicular to the propagation axis Z. The same applies for the magnetic field which has been represented in FIG. 2 as oscillating along the X axis. If the electric field does not rotate around the propagation axis as the electromagnetic wave propagates, the electromagnetic wave is defined as being linearly polarized. If the electric field rotates around the propagation axis as the electromagnetic wave propagates, the electromagnetic wave is defined as being unpolarized. The nature of the polarization can be further defined by the angle between the plane of incidence onto the source of deposition material and the electric field of a linearly polarized beam. As shown in FIG. 3, the electromagnetic wave is described as P-polarized when the electric field is parallel to the incidence plane onto the source of deposition material and S-polarized when the electric field is perpendicular to the incidence plane onto the source of deposition material. Therefore, one can define an angle φ, as shown in FIG. 4 between the electrical field component of the propagating pulsed laser beam and the plane of incidence of the pulsed laser beam onto the source of material deposition which characterized more accurately the state of polarization such as a P-polarized pulsed laser beam having an angle φ=0, while S-polarization having an angle φ=π/2. Circular polarization is a unique case wherein two orthogonal electrical fields with the same amplitude and phase difference of π/2 propagates along the same axis. This is equivalent to having an angle φ= π/4 or the average between S and P polarizations.

To demonstrate the advantages related to the present invention we have investigated the deposition of a diamond like carbon film with graphite as the source of deposition material.

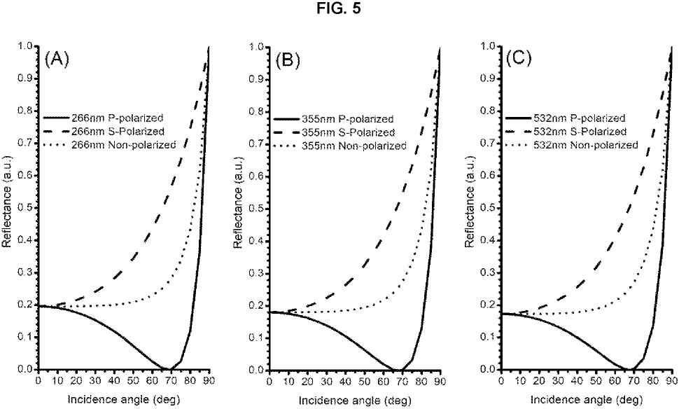

The reflectance of a graphite source of deposition material was calculated at 3 different wavelengths for S-polarized (φ= π/2), P-polarized (φ= 0) and circularly polarized (φ= π/4) laser beams as previously defined. The results of these calculations are shown in FIG. 5. The reflectance of a P-polarization beam can be reduced to zero, regardless of the wavelength, at the Brewster angle. The reader will note that the Brewster angle slightly changes as a function of the considered pulsed laser wavelength in this specific example as the refractive index of the source of material deposition is a function of the wavelength among other variables. The reader will also understand from the teachings of this disclosure that any move away from the widely reported 45 deg incidence angle towards the Brewster angle, with a P-polarized laser pulse, for the particular deposition material will reduce the surface of deposition material reflectance, thereby improving the ablation efficiency, with increasing effect the closer the incidence angle is to the Brewster angle.

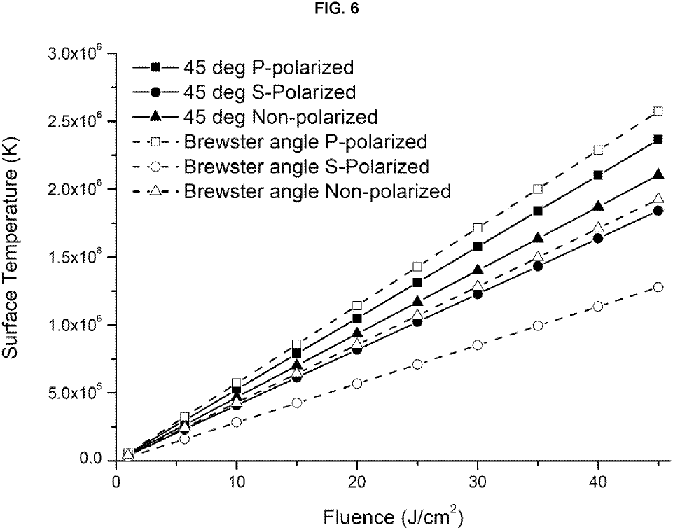

The temperature at the surface of the graphite source of deposition material was also calculated, following the formalism of equation (1), and the results shown in FIG. 6 for a 532 nm excitation, as function of the laser fluence for the 3 polarization states aforementioned and two distinct incidence angles: 45 degrees and the Brewster angle (θ_{B}=67.59 degrees with respect to the normal on the graphite source of deposition material).

$${T}_{s} = \frac{F \left(1 - R\right) α}{ρ {C}_{F}}$$

F is the laser fluence (J/cm²), R, α (5.68×10⁴ cm⁻¹), ρ (1.4 g/cm³) and C_{F} (710 J kg⁻¹ K⁻¹) are the target reflectance, absorption coefficient, density and heat capacitance respectively.

It can be clearly seen, in FIG. 6, that the surface temperature varies linearly with the pulse laser fluence and that the maximum surface temperatures are obtained for a P-polarized beam incidence at the Brewster angle. Selecting a P-polarized beam over a S-polarized beam allows for a 28% increase of the surface temperature at the same fluence and 12% increase for a circularly polarized beam regardless of the incidence angle. A further 9% increase of the surface temperature is achieved by changing the incidence angle of a P-polarized beam from 45 degree to the Brewster angle.

Similarly, the kinetic energy of the ejected carbon atom can be calculated from their velocity (E=0.5mv²) where the total velocity (v) is the sum of three different contributions, the thermal velocity v_{T}, the plasma expansion velocity vₖ and the Coulomb acceleration v_{c} for the charge species.

$${v}_{T} = \sqrt{\frac{8 k {T}_{s}}{π \text{} m}}$$

Where Tₛ is the surface temperature, m the mass of the considered species, and k the Boltzmann constant (1.38×10⁻²³ m² kg s⁻² K⁻¹).

$${v}_{K} = \sqrt{\frac{γ k T}{m}}$$

Where y is the adiabatic coefficient (y=1.67 for monoatomic species).

$${v}_{C} = \sqrt{\frac{2 e z {V}_{0}}{m}}$$

Where e is the electron charge (1.602×10⁻¹⁹ C), z the charge state (i.e. 1+, 2+, 3+ or 4+) and V₀ the equivalent plasma acceleration voltage (~70 V measured experimentally from the electron velocity).

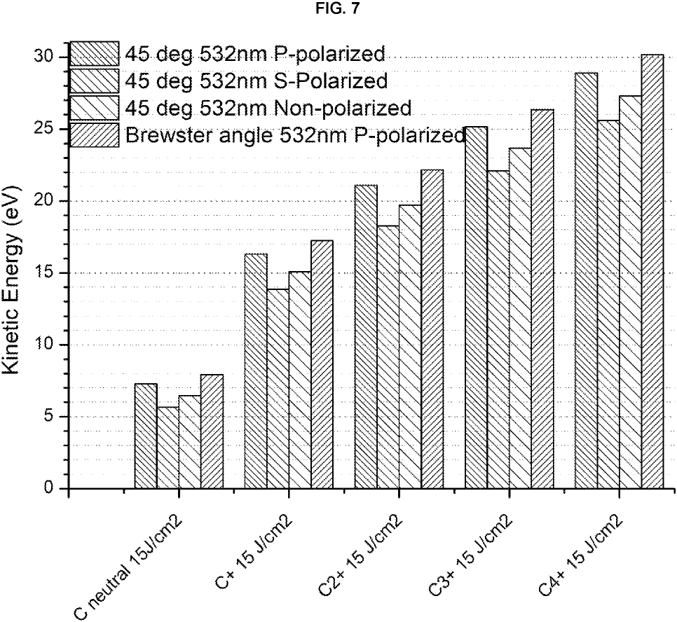

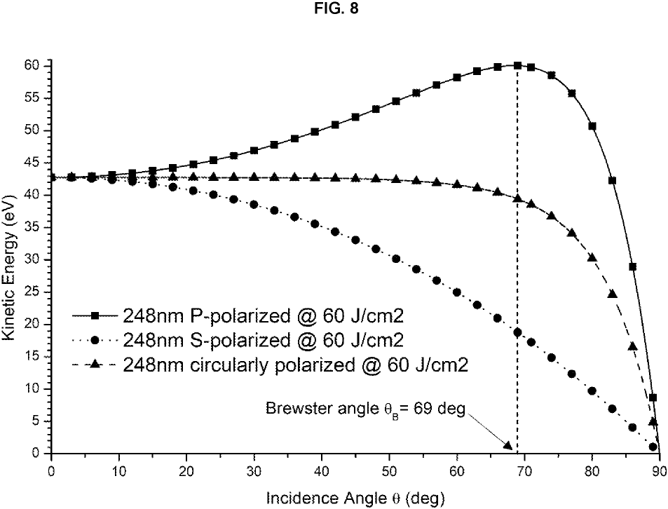

It can be seen in FIG. 7 that the kinetic energy of the ablated material from the source of deposition material is always higher when using a P-polarized beam compared to both the S-polarized and circularly polarized pulsed laser source, regardless of the incidence angle. Increasing the incidence angle from 45 degrees to the Brewster incidence angle further increases the kinetic energy of the ablated carbon atoms and ion species. The same trend is further demonstrated in FIG. 8, which shows the kinetic energy of neutral carbon atoms ablated from a graphite source of deposition material as a function of the incidence angle. It can be clearly seen in FIG. 8 that using a P-polarized pulsed laser offers significant benefits compared with the other polarization states (i.e. S-polarized and circular polarization) regardless of the incidence angle. However, the kinetic energy reaches a maximum when the P-polarized pulsed laser is impinging the source of deposition material at the Brewster angle. A person skilled in the art would also appreciate that any deviation from the absolute value of the Brewster angle and polarization angle φ=0 defining the P-polarisation state will still provide some improvement on the kinetic energy of the ablated atoms and ion species as shown in FIG. 8.

The increase of the kinetic energy is not the same for all generated species. The kinetic energy of highly charged ions is dominated by the Coulomb acceleration which is independent of the plasma temperature in the formalism used here. The increase of kinetic energy for neutral species, which are not influenced by the Coulomb acceleration follows the increase of the plasma temperature as a function of the incidence angle and polarization.

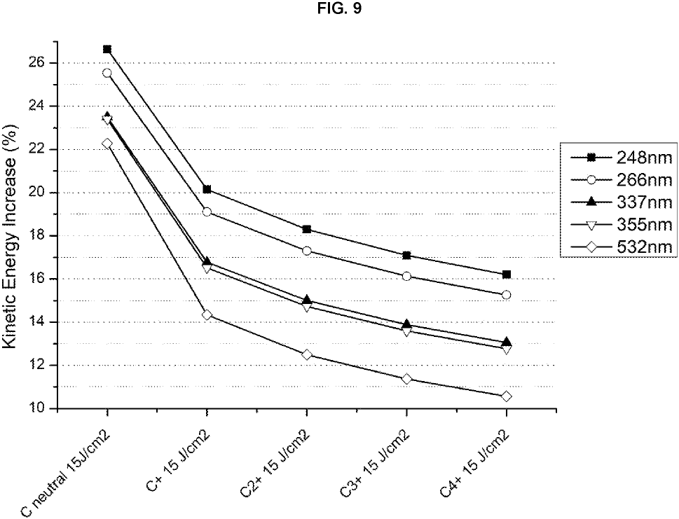

The benefit of this approach is even greater at shorter wavelengths, as it can be seen in FIG. 9 which shows the calculated kinetic energy increase for carbon species between a P-polarized pulsed laser beam at Brewster angle incidence against a circularly polarized pulsed laser beam at 45 deg incidence for different wavelengths.

In relation to optimal wavelengths to be used, preferably they are in the UV region of the optical spectrum, ranging from 126 to 355 nm and typically 193 or about 193 nm, or 198 or about 198 nm or 248 nm or about 248 nm.

In some embodiments, shorter wavelengths are used, for example with an excimer laser, for example Ar₂ at 126 nm, Kr₂ at 146 nm, F₂ at 157 nm, Xe₂ at 172 nm. Such shorter wavelengths are generally less efficient and more difficult to handle.

However, any wavelength may work under the right conditions, provided that the pulse energy is sufficient. The longer the wavelength the higher the energy requirement. In some embodiments, greater wavelengths such as within the visible or Near Infra-Red parts of the spectrum may be used. For example, the wavelengths may be 532 nm (visible), 1064 nm (NIR) or 10.6 µm (IR). However, these are generally not as suitable as they result in higher surface roughness in the deposited thin films which may be detrimental for the envisioned application of the deposited thin film such as for example anti-reflection coatings.

For diamond like coatings, it is widely believed that C⁺ are responsible for generating the Sp3 hybridization which gives these films their unique physical properties. It is also believed that the highest Sp3 fraction is achieved when C⁺ kinetic energy reaches 60 eV. Using a frequency double YAG laser (λ=532 nm), circularly polarized at 45 deg incidence angle and following the same formalism for the calculation of the kinetic energy described above, a fluence of ~85 J/cm² is required. This fluence requirement falls to ~77 J/cm² for a P-polarized beam at the Brewster incidence angle. This value can be further reduced by using shorter wavelengths such as 248 nm produced by an Excimer laser with Krypton Fluoride (KrF) as the gain medium. In this case, only a pulsed laser fluence of 60 J/cm² is required to achieve the required C⁺ kinetic energy of 60 eV, provided that the pulsed laser beam is P-polarized and the incidence angle on the source of deposition equal the Brewster angle (i.e. θ_{B} = 69 deg).

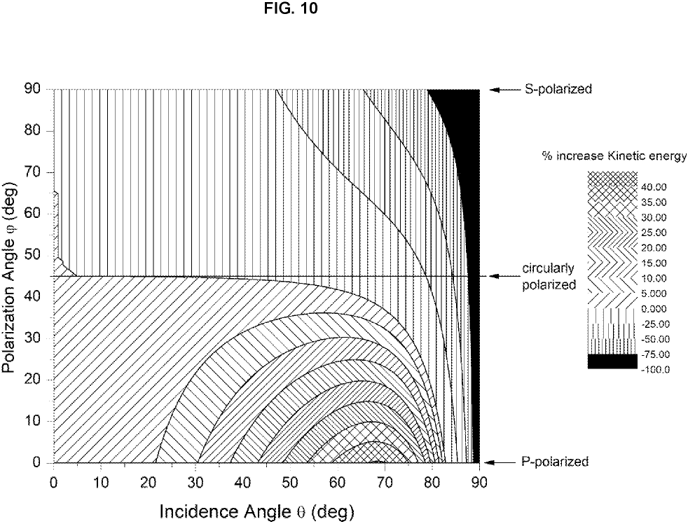

FIG. 10 depicts an even more detailed picture of the enhancement of the kinetic energy of the carbon neutral atoms ejected from the graphite source of deposition material upon its interaction with the pulsed laser beam produced by an excimer laser emitting at 248 nm with a 60 J/cm² fluence. The contour plot shown in FIG. 10 shows the percentage increase of kinetic energy as a function of both the incidence angle θ and the polarization angle φ previously defined. The percentage increase has been calculated by normalizing the kinetic energy of every data point by the kinetic energy achieved at normal incidence angle (θ=0), which is the same for all polarization states. Therefore, the normalized values, shown as a percentage increase of the kinetic energy, are independent from the laser fluence for that particular wavelength. As previously demonstrated the maximum enhancement is achieved for a P-polarized pulsed laser beam (φ=0) with an incident angle θ equal to the Brewster angle, thereby yielding a 40% increase of the kinetic energy. However, someone skilled in the art will appreciate that other combination of incidence angle and polarization angle will yield an increase of the kinetic energy of the ablated carbon atoms, albeit lower than the optimal configuration with θ=θ_{B} and φ=0.

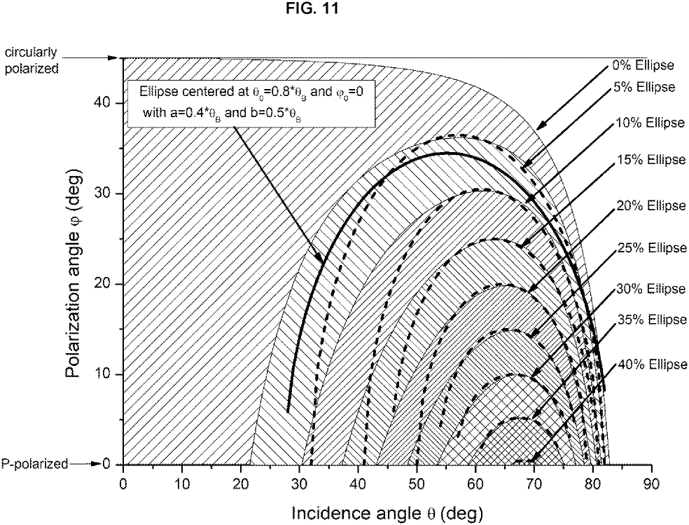

The isolines of the contour plot, which are delimitating the percentage increase of the kinetic energy of the ablated atom from 0% to the maximum increase (i.e. 40%) with a 5% increment are shown in FIG. 11. Although the isolines have complex non-symmetrical shapes, one can roughly approximate their shapes with ellipses, shown as dashed lines in FIG. 11 for each isoline. The equation (5) describes the ellipse where θ is the angle of incidence, φ the polarization angle, θ₀ and φ₀ the coordinate for the centre of the ellipse, a and b the length of the short and long axis respectively.

$$\frac{{\left(θ - {θ}_{0}\right)}^{2}}{{a}^{2}} + \frac{{\left(φ - {φ}_{0}\right)}^{2}}{{b}^{2}} = 1$$

The table 1 shows the parameters used for defining the different ellipses fitting the isolines as function of θ_{B}. Examining the table 1, someone skilled in the art will appreciate that the higher the isoline threshold, the closer the fitting parameter to the ideal values of θ₀=θ_{B} and φ₀=0 describing the ideal condition of a P-polarized pulsed laser with an incidence angle equal to the Brewster angle. However, some improvement can be seen even when deviating from the ideal conditions. For example, a linearly polarized pulsed laser beam with a polarization angle φ=20 deg and an incidence angle θ=52 deg will still produce a 15% increase of the ablated atoms kinetic energy. Generally, any combination of incidence and polarization angles, θ and φ defined by the area under the graphical representation of the ellipse of equation (5) with θ₀=0.8 × θ_{B}, φ₀=0, a=0.4 × θ_{B} and b=0.5 × θ_{B} will result in an increase of the kinetic energy as shown in FIG. 11.

TABLE 1

Fitting Parameters for the Ellipses Describing the Isolines
Isoline threshold - % increase in kinetic energy

| Fitting parameters | 5% | 10% | 15% | 20% | 25% | 30% | 35% | 40% |
|---|---|---|---|---|---|---|---|---|
| θ₀ (deg) | 0.83 × θ_{B} | 0.88 × θ_{B} | 0.91 × θ_{B} | 0.93 × θ_{B} | 0.95 × θ_{B} | 0.96 × θ_{B} | 0.98 × θ_{B} | 0.99 × θ_{B} |
| φ₀ (deg) | 0 | 0 | 0 | 0 | 0 | 0 | 0 | 0 |
| a (deg) | 0.36 × θ_{B} | 0.29 × θ_{B} | 0.25 × θ_{B} | 0.21 × θ_{B} | 0.17 × θ_{B} | 0.14 × θ_{B} | 0.10 × θ_{B} | 0.03 × θ_{B} |
| b (deg) | 0.52 × θ_{B} | 0.44 × θ_{B} | 0.36 × θ_{B} | 0.29 × θ_{B} | 0.22 × θ_{B} | 0.14 × θ_{B} | 0.07 × θ_{B} | 0.01 × θ_{B} |

This reduction of the required fluence obtained with this invention allows for increased deposition speed. For example, with the same laser power output, a larger spot size on the target can be used with a P-polarized beam at the Brewster angle, yielding the same fluence, enabling larger quantities of material being removed from the target, thereby increasing the deposition speed.

Another benefit of a large incidence angle relates to surface contamination on the optics, especially the window 10 in FIG. 1 which allows for the incoming pulsed laser beam to penetrate the vacuum chamber. Over time the optics, especially when the incidence angle is at or about 45 deg, are subjected to the deposition of the material ablated from the source of deposition material albeit at a much lower rate than the substrate meant to be coated. Increasing the incidence angle towards the Brewster angle reduces the coating rate of the optics, reducing the need for replacing them every so often.

Furthermore, the larger than standard incidence angle allows for reducing the distance between the source of deposition material and the substrate due to the lower encumbrance. This smaller gap also enables larger deposition rates as it has been shown that the deposition rate is inversely proportional to the distance between the target and the substrate. This is due to the increase of hemispherical expansion of the pulsed laser induced plasma plume with the increase of the source of deposition material to substrate distance. In other words, while positioning the substrate closer to the source of deposition material allows only a smaller surface to be coated, the conservation of the ion flux implies that a thicker coating can be achieved for a given deposition time. This is particularly relevant for the coating of substrates with a small surface area, such as lenses for example.

When applying PLD to the deposition of complex metal oxides, changing the distance between the target and the substrate can influence the stoichiometry for the deposited material. Using the apparatus and method described allows for an alternative way to achieve better control.

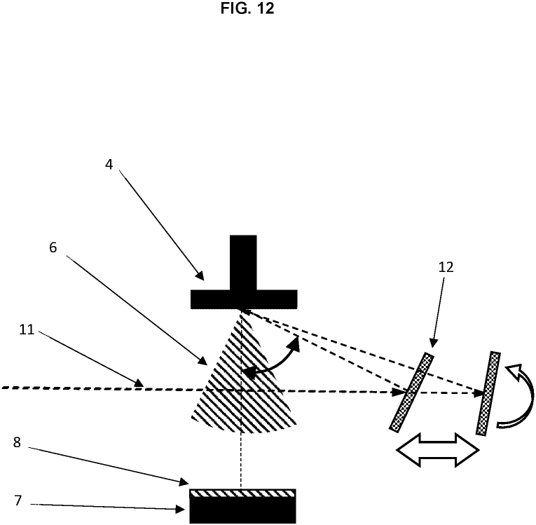

While for most applications a vacuum chamber will be ideally dedicated to the deposition of a single material to avoid cross contamination and therefore costly down time in an industrial setting, it is easy to envision a simple mechanical device for readily adjusting the incidence angle. Such adjustment may preferably occur within the vacuum chamber to access a wider range of incidence angle as steering the pulsed laser beam outside the chamber would only allow for few degrees variation of the incidence angle. An example of such device is depicted in FIG. 12 where a P-polarized pulsed laser beam 11 is directed onto a mirror 12. The mirror 12 reflects the P-polarized pulsed laser beam 11 onto the target 4 at a predefined incidence angle corresponding to the Brewster angle for the given target 4, to produce a plasma plume 6 of ionized species which will condense on the substrate 7 to form the thin film 8. The position of the mirror 12 can be modified manually through both translation and rotation mechanical devices to adjust the pulsed laser beam incidence angle depending on the nature of the source of deposition material, ensuring that the pulsed laser beam incidence angle moves toward or preferably matches the Brewster angle. Alternatively, these translation and rotation adjustments can be performed through computer controlled motorised translation and rotation mechanical devices.

The mirror can be provided in any suitable shape or form. Typically, they are either circular or square. Preferably, when used with an excimer laser, the mirror is a dielectric mirror, which reflects only the desired wavelength or wavelength range they are designed to reflect and are otherwise transparent (or semitransparent). Metallic mirrors, such as Aluminium can also be used for UV applications (down to 250 nm) but are not as resilient as dielectric ones as they can not sustain high energy density. In practice, mirrors can be glued on a plate, or mounted on a ring, or clamp.

Another option is to change the position of the target, through similar rotation and translation mechanical devices, to modify the incidence angle without having to adjust the pulsed laser optical pathway. However, this option would only work for flat targets and not cylindrical ones. Furthermore, tilting the source of deposition material will also tilt the generated plasma plume created upon impact of the pulsed laser beam onto the target, as it is always perpendicular to the target surface, therefore requiring the substrate to be repositioned with respect to the target accordingly. Consequently, while technically feasible, this approach is more complex than steering the pulsed laser beam. Any variation of the aforementioned pulsed laser beam steering architecture or any other means of steering the incident laser beam onto the target material 4 would be adequate for matching the incidence angle with the Brewster angle, or moving towards the Brewster angle from the standard 45 deg.

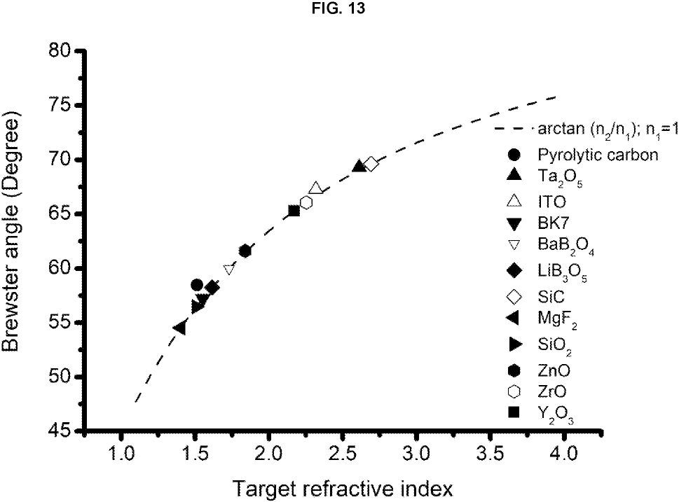

The reader will appreciate that this is only one of many potential applications for this invention which relates to the optimum polarization and incidence angle for pulsed laser beams in PLD. Changing from one source of deposition material to another will require adjustment of the pulsed laser beam incidence angle to the Brewster angle according to the refractive index of the source of deposition material as shown in FIG. 13. While PLD, and therefore this invention, can be used for the deposition of virtually any materials, including metals, semiconductors and organic materials such as polymers, this deposition method and the present invention are particularly suited for the deposition of complex metal oxides such Lithium Niobate (LiNbO₃), high temperature superconductors such as LiTi₂O₄, Li₄Ti₅O₁₂ and YBa₂Cu₃O₇, ferroelectric materials such as BaₓSr₁₋ₓTiO₃, piezoelectric such as Ta₂O₅, fast ion conductors Y₂(Sn_{y}Ti_{1-y})₂O₇ and liquid petroleum gas sensors such as Pd-doped SnO₂ to name a few, which are known to be difficult to achieve with any other physical or chemical deposition methods due to their complex stochiometric composition. The aforementioned advantages (i.e. lower energy requirement, higher ablation efficiency, higher deposition speed and so on), demonstrated with Diamond Like Carbon deposition from a graphite source of deposition, can be replicated with any material.

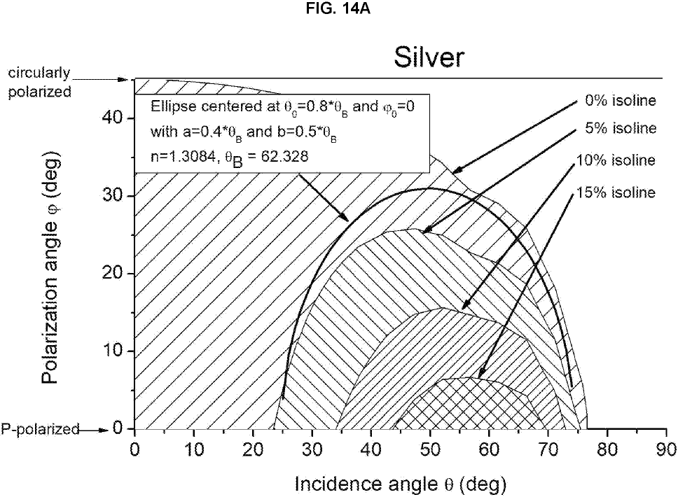

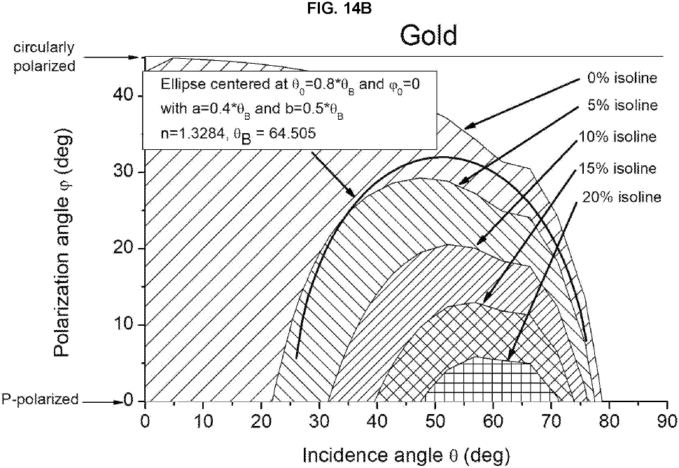

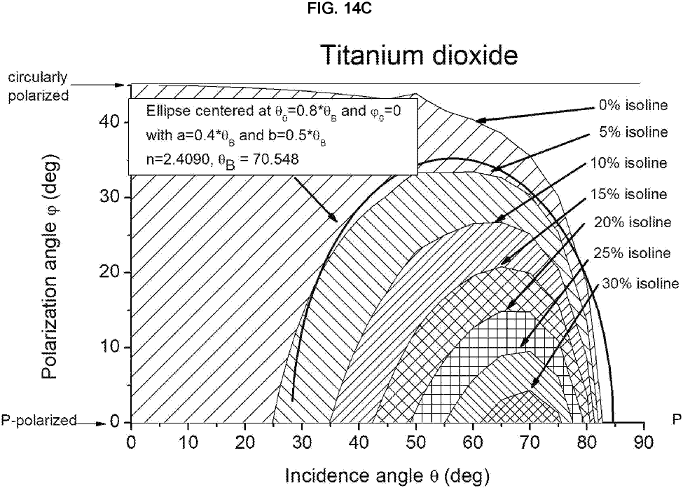

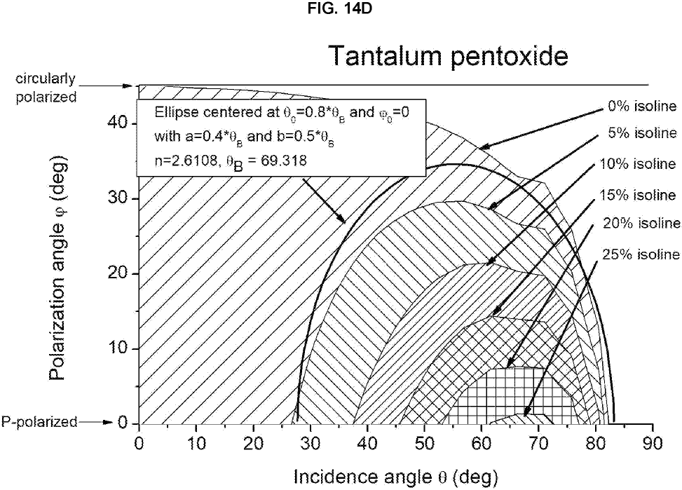

The same calculations, as previously shown for graphite ablation and the resulting carbon atom increase of kinetic energy, have been reproduced with other materials commonly used in physical deposition methods such as silver, gold, titanium dioxide (TiO₂) and tantalum pentoxide (Ta₂O₅). These materials have been selected to demonstrate the viability of this invention over a wide range of refractive index n₂ from 1.3 to 2.6 at 248 nm for the source of deposition material. FIGS. 14A-14D shows, similarly to FIG. 11, the isolines describing the percentage increase of the ablated atoms from each of these materials ((A): silver, (B):gold, (C): TiO₂ and (D): Ta₂O₅) upon interaction with the pulsed laser beam as a function of the polarization angle and incidence angle. Someone skilled in the art will appreciate that the magnitude of enhancement (i.e. percentage increase of the resulting kinetic energy of the ablated specie) is highly dependent on the nature of the material and more specifically on its heat capacitance and absorbance at the considered wavelength. Nevertheless, a significant increase of the kinetic energy can be observed for all the materials studied, ranging from over 15% for gold to over 30% for TiO₂. It will be also noted that the best fitting ellipse, shown on each plot of FIG. 13 is a plain line, described by the equation 5, with θ₀=0.8 × θ_{B}, φ₀ = 0, a = 0.4 × θ_{B} and b=0.5 × θ_{B} is consistently overlapping the area of the different plots of FIG. 14 where there is a significant enhancement of the kinetic energy compared to the standard ablation conditions with a 45 deg incidence angle and unpolarized pulsed laser.

It is convenient to describe the invention herein in relation to particularly preferred embodiments. However, the invention is applicable to a wide range of embodiments and it is to be appreciated that other constructions and arrangements are also considered as falling within the scope of the invention. Various modifications, alterations, variations and or additions to the construction and arrangements described herein are also considered as falling within the ambit and scope of the present invention.

What is claimed is:

1-42. (canceled)

43. A thin film deposition apparatus comprising:
a laser pulse generator to generate a laser pulse;
optical elements to P-polarize and rotate the laser pulse polarization with a polarization angle φ based on the cavity chamber and deposition material;
focusing optics to focus the laser pulse;
a source of deposition material having refractive index n₂;
said deposition material mounted within an evacuated chamber having a refractive index n₁ a rotation and / or translation device to alter and / or direct said laser pulse onto said source of deposition material at an incidence angle θ to produce a plasma to be deposited on a substrate;
wherein the polarization angle φ and incidence angle θ are defined by the area under the graphical representation of the ellipse of equation
$$\begin{matrix}\frac{{\left(θ - {θ}_{0}\right)}^{2}}{{a}^{2}} + \frac{{\left(φ - {φ}_{0}\right)}^{2}}{{b}^{2}} = 1 \text{where} {\text{θ}}_{0} = 0.8 \times \text{arctan} \left({\text{n}}_{2} / {\text{n}}_{1}\right) , {\text{φ}}_{0} = \\ 0 , \text{a} = 0.4 \times \text{arctan} \left({\text{n}}_{2} / {\text{n}}_{1}\right) \text{and b} = 0.5 \times \text{arctan} \left({\text{n}}_{2} / {\text{n}}_{1}\right)\end{matrix}$$
.

44. The thin film deposition apparatus according to claim 43 wherein the laser pulse generator comprises an excimer laser pulse generator.

45. The thin film deposition apparatus according to claim 44 wherein the excimer laser pulse generator comprises KrF as gain medium.

46. The thin film deposition apparatus according to claim 43 wherein the laser pulse generator comprises ArF as gain medium.

47. The thin film deposition apparatus according to claim 43 wherein the laser pulse wavelength is less than 1064 nm.

48. The thin film deposition apparatus according to claim 43 wherein the laser pulse wavelength is less than 600 nm.

49. The thin film deposition apparatus according to claim 43 wherein the laser pulse wavelength is about 532 nm.

50. The thin film deposition apparatus according to claim 43 wherein the laser pulse wavelength is in the range 213 to 355 nm.

51. The thin film deposition apparatus according to claim 43 wherein the laser pulse wavelength is in the range 126 to 348 nm.

52. The thin film deposition apparatus according to claim 43 wherein the laser pulse wavelength is 248 nm or about 248 nm.

53. The thin film deposition apparatus according to claim 43 wherein the laser pulse wavelength is 198 nm or about 198 nm.

54. The thin film deposition apparatus according to claim 43 wherein the laser pulse wavelength is 193 nm or about 193 nm.

55. The thin film deposition apparatus according to claim 43 wherein the pulse duration is in the range 1 femtosecond to 50 nanoseconds.

56. The thin film deposition apparatus according to claim 43 wherein the pulse duration is in the range 5-30 nanoseconds.

57. The thin film deposition apparatus according to claim 43 wherein the optical elements to P-polarize and rotate the laser pulse polarization comprises one or more of a film polarizer, a crystal polarizing cube, a wire grid polarizer, a Brewster window, a λ/4 plate, a λ/2 plate, and a faraday rotator.

58. The thin film deposition apparatus according to claim 43 wherein the deposition material comprises one or more of: a carbon source, a graphite, highly oriented pyrolytic graphite, a complex metal oxide, Lithium Niobate (LiNbO₃), a high temperature superconductor, LiTi₂O₄, Li₄Ti₅O₁₂, YBa₂Cu₃O₇, a ferroelectric material, BaₓSr₁₋ₓTiO₃, a piezoelectric, Ta₂O₅, a fast ion conductor, Y₂(Sn_{y}Ti_{1-y})₂O₇, a liquid petroleum gas sensor, and Pd-doped SnO₂.

59. The thin film deposition apparatus according to claim 43 wherein the pressure within the evacuated chamber is in the range 10⁻⁴ to 10⁻⁸ Torr.

60. The thin film deposition apparatus according to claim 43 wherein the pressure within the evacuated chamber is in the range 10⁻⁶ to 10⁻⁸ Torr.

61. The thin film deposition apparatus according to claim 43 wherein the polarization angle φ and incidence angle θ are defined by the area under the graphical representation of the ellipse of equation
$$\frac{{\left(θ - {θ}_{0}\right)}^{2}}{{a}^{2}} + \frac{{\left(φ - {φ}_{0}\right)}^{2}}{{b}^{2}} = 1$$
where θ₀=arctan (n₂/n₁), φ₀=0, a=1 and b=1.

62. A thin film deposition apparatus comprising:
an excimer laser pulse generator with KrF as gain medium to generate a laser pulse with wavelength of 248 nm and pulse duration of 5 to 30 nanoseconds;
a set of optical elements, comprising a sequence of λ/4 plate, then λ/2 plate then λ/4 plate to linearly P-polarize the laser pulse and rotate the laser pulse polarization with a polarization angle φ based on the cavity chamber and deposition material;
focusing optics to focus the laser pulse;
a source of deposition material comprising highly oriented pyrolytic graphite and having refractive index n₂;
said deposition material mounted on a rotation and / or translation device within an evacuated chamber having a refractive index n₁ and pressure within the evacuated chamber in the range 10-⁶ to 10⁻⁸ Torr;
a rotation and / or translation device comprising a dielectric mirror, for readily altering and directing said laser pulse onto said source of deposition material at an incidence angle θ to produce a plasma;
a substrate;
means for positioning said substrate to be in the path of said plasma so that said plasma is directed towards said substrate;
wherein the polarization angle φ and incidence angle θ are defined by the area under the graphical representation of the ellipse of equation
$$\begin{matrix}\frac{{\left(θ - {θ}_{0}\right)}^{2}}{{a}^{2}} + \frac{{\left(φ - {φ}_{0}\right)}^{2}}{{b}^{2}} = 1 \text{where} {\text{θ}}_{0} = \text{arctan} \left({\text{n}}_{2} / {\text{n}}_{1}\right) , {\text{φ}}_{0} = \\ 0 , \text{a} = 1 \text{and b} = 1.\end{matrix}$$
.
